(19) United States
(12) Patent Application Publication
(10) Pub. No.: US 2006/0055050 A1
(43) Pub. Date: Mar. 16, 2006

(54) Semiconductor device and manufacturing method thereof

(76) Inventors: Hideo Numata, Yokohama-shi (JP); Hirokazu Ezawa, Tokyo (JP); Chiaki Takubo, Tokyo (JP); Kenji Takahashi, Tsukuba-shi (JP); Hideo Aoki, Yokohama-shi (JP); Susumu Harada, Yokohama-shi (JP); Hisashi Kaneko, Fujisawa-shi (JP); Hiroshi Ikenoue, Nankoku-shi (JP); Mie Matsuo, Kamakura-shi (JP); Ichiro Omura, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/221,762

(22) Filed: Sep. 9, 2005

(30) Foreign Application Priority Data
Sep. 10, 2004 (JP) P2004-264729
Sep. 10, 2004 (JP) P2004-264731
Sep. 10, 2004 (JP) P2004-264732

(51) Int. Cl. H01L 23/48

(52) U.S. Cl. 257/774

(57) ABSTRACT

A semiconductor device comprises a semiconductor substrate having an through hole, a first insulation resin layer formed on an inner surface of the through hole, a second insulation resin layer formed on at least one of front and rear surfaces of the semiconductor substrate, and a first conductor layer formed in the through hole to connect at least both front and rear surfaces of the semiconductor substrate and insulated from the inner surface of the through hole with the first insulation resin layer. A second conductor layer (wiring pattern) which is electrically connected to the first conductor layer in the through hole is further provided on the second insulation resin layer. The conductor layer formed in the through hole and constituting a connecting plug has a high insulation reliability. Therefore, a semiconductor device suitable for a multi-chip package and the like can be obtained. Further, since the forming ability of the conductor layer connecting the front and rear surfaces and the insulation layer is high, the manufacturing cost can be reduced.

### CROSS-REFERENCE TO RELATED APPLICATIONS

This application is based upon and claims the benefit of the priority from the prior Japanese Patent Applications No. 2004-264729, No 2004-264731 and No. 2004-264732 filed on Sep. 10, 2004, respectively: the entire contents of which are incorporated herein by references.

### BACKGROUND

1. Field of the Invention

This invention relates to a semiconductor device which can be applied as a multi-chip package having a plurality of semiconductor elements (semiconductor chips) and a manufacturing method thereof.

2. Description of the Related Art

Recently, for realizing a miniaturization and a high density of a semiconductor device, a stacked type multi-chip package, in which a plurality of semiconductor elements (chips) are stacked and sealed in one package, is put to practical use. Generally, in the stacked type multi-chip package, respective electrode pads of a plurality pf semiconductor chips and an electrode portion of a substrate are electrically connected with a wire-bonding. Further, when connecting mutually between a plurality of semiconductor chips, respective electrode pads of the plurality of semiconductor chip are electrically connected with the wire bonding therebetween.

As in such stacked type multi-chip package, a package structure, in which the wiring bonding is applied to the connection between the semiconductor chip and the substrate, or between the plurality of semiconductor chips, causes an increase of manufacturing cost due to the cost necessary for the connecting processes and the man hours. And in addition to a longer signal wiring length, it has a problem that the shape of package becomes larger.

Therefore, a stack type multi-chip package, in which a through plug (connecting plug) and a through via are applied to a connection between a semiconductor chip and a substrate and between a plurality of semiconductor chips, is proposed (for example, refer to Japanese Patent Laid-open Application No. Hei 10-223833).

A connecting plug applied to the connection between semiconductor chips, for example, has a structure in which a metal within a through hole that is formed so as to passing through both front and rear surfaces of a semiconductor substrate, to form a conductor layer. To connect between the connecting plug and an electrode pad on a front surface of the semiconductor substrate, a wiring technique using conventional semiconductor processes can be applied.

Further, the conductor layer constituting the connecting plug is necessary to insulate from a front surface of the semiconductor substrate and an inner surface (inside wall surface) of the though hole. As those insulation, an inorganic insulation layer such as a SiO₂ layer, a Si₃N₄ layer, or a laminated film thereof which is formed by a CVD method (LPCVD method) is used.

However, it is difficult to uniformly form the above-mentioned inorganic insulation layer such as a SiO₂ layer, a Si₃N₄ layer and the like on the inner surface of the through hole. Particularly, it is difficult to form a thick film thereof. Therefore, the inorganic insulation layer formed by applying a conventional semiconductor process has a main cause that an insulation reliability of the plug connecting the front and rear surfaces is decreased.

Further, when forming an inorganic insulation layer on an inner surface of the through hole, there is a problem that the filling of conductive material such as a metal and the like within the through hole is technically difficult. With regard to the problem, similarly to a conventional through hole, the conductor layer can be formed only at inside wall surface of the through hole. However there is a problem that a mechanical strength of the semiconductor chip is decreased.

The invention has been made to cope with the above problems. An object of the invention is to provide a semiconductor device and a manufacturing the same, in which the forming property of the conductive layer connecting both front and rear surfaces of the semiconductor substrate and the insulation layer can be improved, the forming cost thereof can be down, while the insulation reliability of the conductor layer which constitutes the connection plug and the like being improved.

### SUMMARY

A first aspect of the present invention is a semiconductor device comprising a semiconductor substrate having a through hole passing through between a front surface and a rear surface, a first insulation resin layer formed on an inner surface of the through hole, a second insulation resin layer formed on at least one of the front and rear surfaces of the semiconductor substrate, and a first conductor layer formed in the through hole to electrically connect between the front and rear surfaces of the semiconductor substrate, wherein the first conductor layer is insulated from the inner surface of the through hole with the first insulation resin layer.

A second aspect of the present invention is a manufacturing method of a semiconductor device comprising forming a through hole by irradiating a laser on a semiconductor substrate having an integrated element formed at a front surface thereof, filling an insulation resin into the through hole, forming concentrically a resin hole having a diameter smaller than that of the through hole, and forming a conductor layer on an inner surface of the resin hole and forming a through hole conductive portion to electrically connect between the front surface and the rear surface of the semiconductor substrate.

A third aspect of the present invention is a manufacturing method of a semiconductor device comprising forming a through hole in a semiconductor substrate, disposing each resin sheet, which has a copper foil at one side thereof, on the both surfaces of the semiconductor substrate to contact with a resin surface of the each resin sheet, and laminating the disposed each resin sheet and the semiconductor substrate, forming a small hole having a diameter smaller than that of the through hole at a portion of the through hole, forming a conductor layer inside of the small hole, and electrically connecting the conductor layer with the copper foil disposed on both surfaces of the semiconductor substrate, and processing the copper foil to form a wiring.

A fourth aspect of the present invention is a manufacturing method of the semiconductor device comprising forming a through hole in a semiconductor substrate, forming a porous insulation resin layer to cover a front surface and a rear surface of the semiconductor substrate including an inside of the through hole, and forming a conductor layer within the porous insulation resin layer to connect at least between the front surface and the rear surface of the semiconductor substrate, while maintaining an insulation state from the front and rear surfaces of the semiconductor substrate and from an inner surface of the through hole.

### BRIEF DESCRIPTION OF THE DRAWINGS

The present invention will be described with reference to drawings. But the drawings are provided to illustrate, and do not limit the invention.

FIG. 1 is a cross sectional view showing a structure of a semiconductor device according to a first embodiment of the present invention.

FIGS. 2A, 2B, 2C, 2D and 2E are cross sectional views showing first half processes for manufacturing the semiconductor device according to a second embodiment of the present invention.

FIGS. 2F, 2G, 2H and 2I are cross sectional views showing intermediate processes for manufacturing the semiconductor device according to a second embodiment of the present invention.

FIGS. 2J, 2K and 2L are cross sectional views showing latter half processes for manufacturing the semiconductor device according to a second embodiment of the present invention.

FIG. 3 is a cross sectional view showing a structure of a semiconductor device according to a third embodiment of the present invention.

FIG. 4 is a cross sectional view showing a structure of a semiconductor device according to a fourth embodiment of the present invention.

FIG. 5 is a cross sectional view showing a structure of a stacked package using a semiconductor device according to a fourth embodiment of the present invention.

FIGS. 6A, 6B, 6C, 6D, 6E, 6F and 6G are cross section views showing a manufacturing process of a semiconductor device according to a fifth embodiment of the present invention.

FIG. 7 is a cross sectional view showing a structure of a semiconductor device according to a sixth embodiment of the present invention.

FIGS. 8A, 8B, 8C, 8D, 8E, 8F and 8G are cross section views showing a manufacturing process of a semiconductor device according to a seventh embodiment of the present invention.

FIG. 9 is a cross sectional view showing a structure of a semiconductor device according to a eighth embodiment of the present invention.

FIGS. 10A, 10B, 10C, 10D, 10E, 10F, 10G and 10H are cross section views showing a manufacturing process of a semiconductor device according to a ninth embodiment of the present invention.

FIG. 11 is a cross sectional view showing a structure of a semiconductor device according to a tenth embodiment of the present invention.

FIG. 12 is a cross sectional view showing another structure of a semiconductor device shown in FIG. 13.

FIGS. 13A, 13B, 13C, and 13D are cross section views showing a manufacturing process of a semiconductor device according to an eleventh embodiment of the present invention.

FIG. 14 is a cross sectional view showing an example of a forming step of porous insulation resin layer in the manufacturing process of a semiconductor device shown in FIG. 15.

FIG. 15 is across sectional view showing another example of a forming step of porous insulation resin layer in the manufacturing process of a semiconductor device shown in FIG. 15.

FIG. 16 is a cross sectional view showing an example of a semiconductor device having a stack type multi-chip structure with a semiconductor device according to a tenth embodiment of the present invention.

### DETAILED DESCRIPTION

According to a semiconductor device and a manufacturing method thereof of one embodiment of the present invention, a through hole has a conductor layer insulated with an insulation layer having a good adhesiveness. Therefore, it is possible to easily obtain a semiconductor device having a high reliability suitable for a multi-chip package on which a plurality of semiconductor chips are stacked mounted with relatively low cost.

Hereinafter, embodiments for implementing the present invention will be described. In the following description, embodiments will be described based on drawings, but the present invention is not limited to the drawings, because the drawings are provided for illustration.

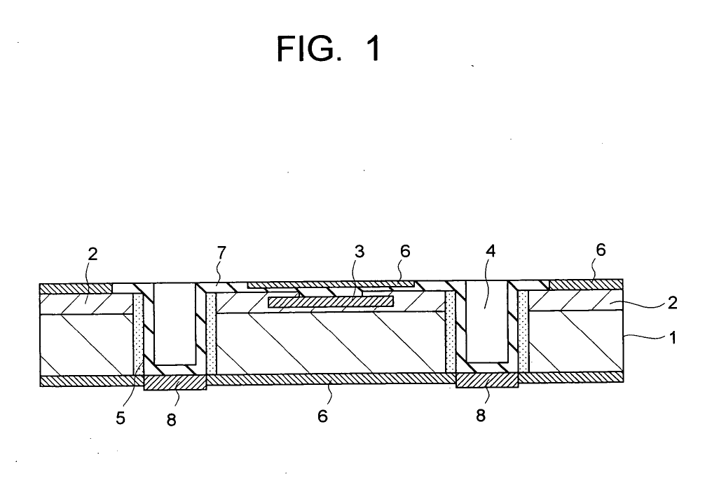

FIG. 1 is a cross sectional drawing showing a structure of a semiconductor device according to a first embodiment of the present invention. Reference number 1 shows a semiconductor substrate such as a silicon substrate having a surface on which functional elements are integrated and formed. That is, at a surface side of the semiconductor substrate 1 which is an element region, an integrated element portion, a multiple layered wiring portion (silicon wiring layer) 2 connecting between respective elements, and the like are formed. Further, on a surface of the semiconductor substrate 1, an Al electrode (pad) 3 connecting to the multiple layered wiring portion being within the semiconductor substrate. The semiconductor substrate 1 has a through hole 4 passing through front and rear surfaces thereof. The through hole 4 is formed by irradiating a laser, and an inner surface (side wall surface) of the through hole 4 is composed of silicon having an amorphous structure.

And, on the inner surface of the through hole 4, a layer composed of a first insulation resin is formed. Here, as the first insulation resin, a polyimide resin, a benzodicyclobutene resin, an epoxy resin, a phenol resin, a cyanate-ester resin, a bis-maleinimide resin, a bis-maleinimide-triazin resin, a polybenzoxazol resin, a butadiene resin, a silicone resin, a polycarbondiimde resin, a polyurethane resin and the likes are used.

Further, on a predetermined region of front and rear surfaces of the semiconductor substrate 1, layers 6 constituting a second insulation resin are formed, respectively. As the second insulation resin, both the same resin as that of the first insulation resin mentioned above and a different resin are allowed to use.

Furthermore, on the first insulation layer 5 in the through hole 4, on a bottom portion of the through hole 4, and in the neighborhood of the through hole 4 at a front surface side of the semiconductor substrate 1, a conductor layer 7 formed of Ti, Ni, Cu, V, Cr, Pt, Pd, Au, Sn, and the like is formed. In addition, in a terminal portion of the through hole 4 at a rear side of the semiconductor substrate 1, a rear surface electrode 8 is formed. As a conductor constituting the rear surface electrode 8, Ti, Ni, Cu. V, Cr, Pt, Pd, Au, Sn and the like can be used. Thus, by the conductor layer 7 formed within the through hole 4, a through hole conductive portion (through via) which electrically connects between the front and rear surfaces of the semiconductor substrate 1 is formed. An Al electrode 3 on the front surface of the semiconductor substrate 1 and the rear surface electrode 8 are connected with the through via.

In the first embodiment described above, as an insulation material which covers an inner surface (inside wall surface) of the through hole 4, an insulation resin (a first insulation resin) is used. Therefore in addition to the low-cost thereof, it is possible to form a thick insulation with stability, thereby a good insulation and a high reliability being secured.

Further, the inside wall surface of the through hole 4 is composed of silicon having an amorphous structure, and further the insulation resin layer (the first insulation resin layer 5) is formed thereon. Therefore, the insulation resin layer has a good adhesiveness with silicon which is a base material. Since silicon has generally a poor adhesiveness with a resin material, when an insulation resin layer is formed in a through hole which is formed on a silicon substrate by the RIE (reactive ion etching) process, the insulation resin layer would be easily peeled off or cracked due to the difference between the thermal expansion coefficient of an insulation resin layer and a conductor layer formed on the insulation resin layer and the thermal expansion coefficient of silicon. However, in the semiconductor device of the first embodiment, since the through hole 4 is formed by the laser irradiation, and the inside wall surface of the through hole 4 is composed of silicon having an amorphous structure, the adhesiveness of the insulation resin layer is high. Consequently, a conductive portion (a through via) having a high reliability can be obtained.

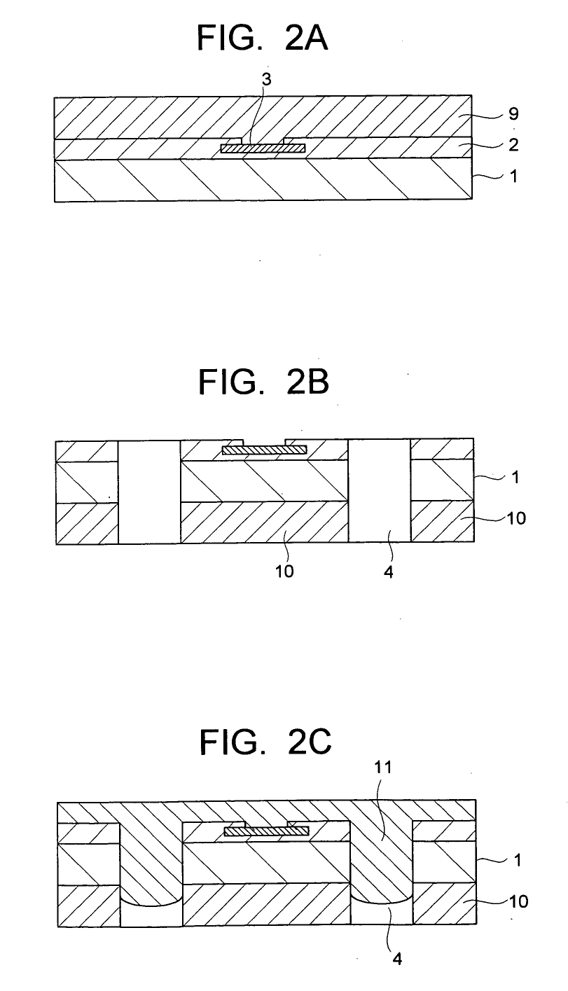

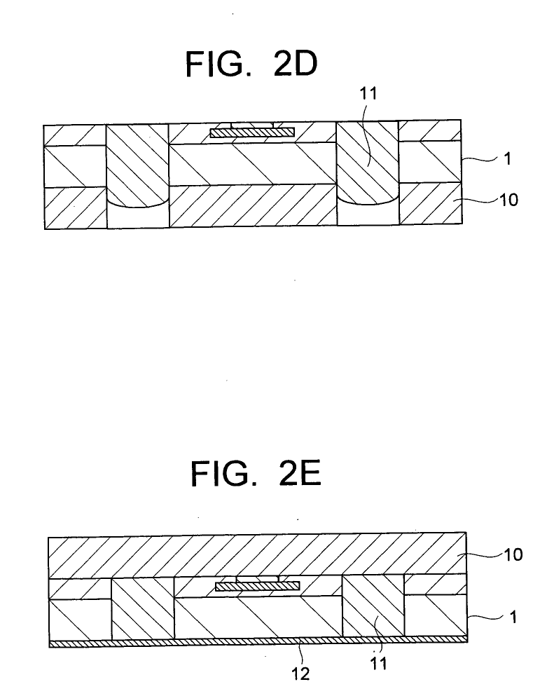

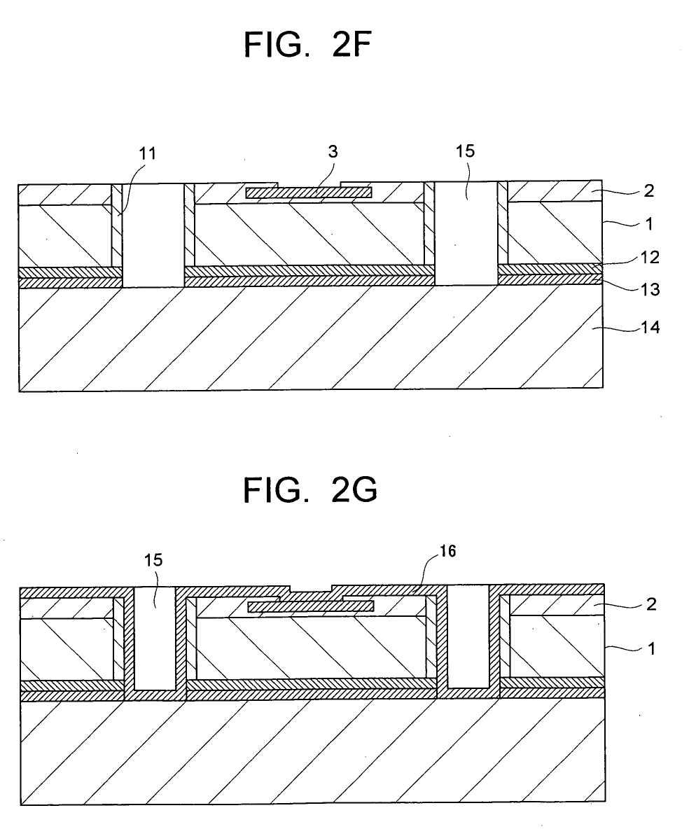

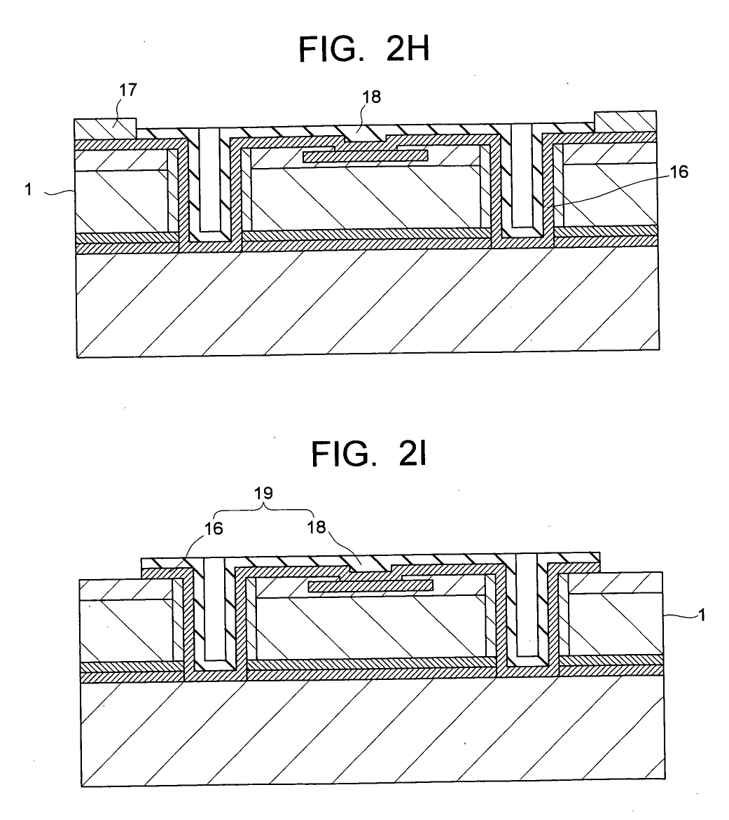

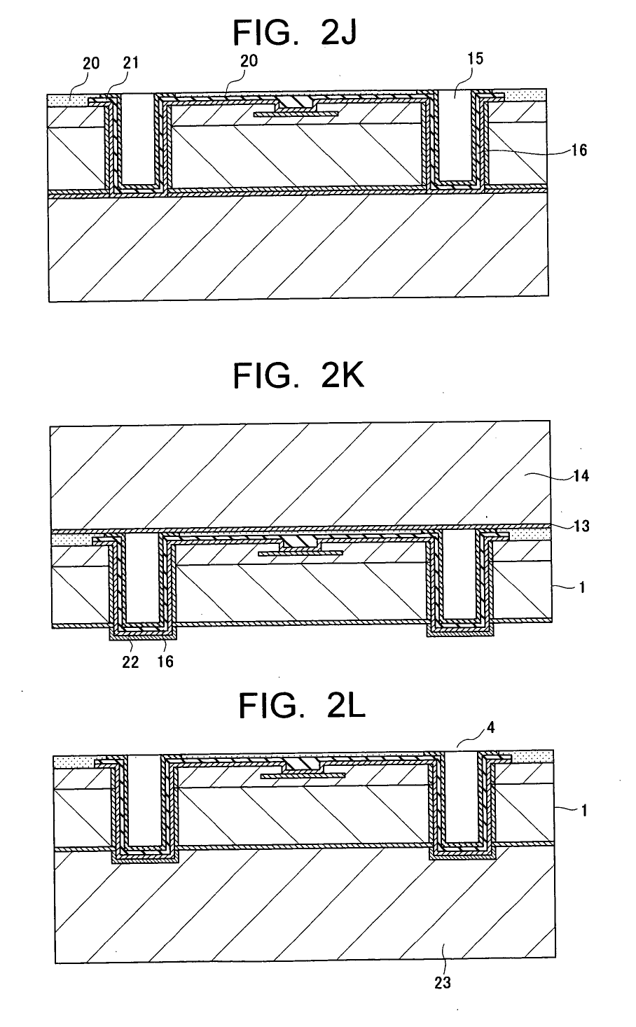

Next, second embodiment which is a manufacturing method of the semiconductor device of the first embodiment will be described with reference to FIGS. 2A to 2L. In the second embodiment, as shown in FIG. 2A, a semiconductor substrate (silicon wafer) 1 having an integrated element portion, a multi-wiring portion (silicon wiring layer) 2 connecting between respective elements, and an Al electrode 3 connecting to the multi-wiring portion on a surface thereof are prepared, and after sticking a BSG tape 9 on the surface, is polished on the rear surface of the semiconductor substrate 1. At the time, to increase the bending strength, the treatment such as a dry polish, RIE, CMP (chemical mechanical polishing) and the like may be allowed.

Next, after peeling off the BSG tape 9, as shown in FIG. 2B, after stacking a holding tape 10 on the rear surface, a through hole 4 is formed in the semiconductor substrate 1 by irradiating a laser. As a laser for irradiating, for example, a YAG laser having a wave length of 355 nm can be used. The wave length of laser is not limited to the value. When making the hole in the semiconductor substrate 1, at the same time, to make a hole in the holding tape 10 is allowed. And after making the hole by the laser, if necessary, cleaning is allowed. In order to prevent the scattering at the time of making a hole, it is allowed to previously form a protecting film on a surface of the semiconductor substrate 1, and remove the protecting film after making the hole.

Subsequently, as shown in FIG. 2C, from the front surface side of the semiconductor substrate 1, an insulation resin 11 such as a polyimide resin is printed thereon, and the insulation resin is filled into the through hole 4. The filling of the insulation resin 11 by the printing may be carried out in a vacuum. When the printing is carried out in a vacuum, it is possible to suppress the occurrence of voids in the insulation resin 11. Further, the filling of the insulation resin 11 into the through hole 4 may be carried out by the roll-coat method. When the hole is also made in the holding tape 10 and the through hole 4 at the side of holding tape 10 is opened, the filling of the insulation resin 11 into the through hole is easy and free from danger.

Next, as shown in FIG. 2D, an insulation resin 11 covered on the front surface of the semiconductor substrate 1 is removed by polishing. This process is carried out in case of need. Then, after a holding tape 10 is renewed, an insulation resin which protrudes from the rear surface is cut off and polished, thereby the rear surface of the semiconductor substrate 1 being flattened. If the amount of protruding is small, the polishing is not carried out.

As shown in FIG. 2E, after the holding tape 10 is stuck on the front surface of the semiconductor substrate 1, an insulation resin film 12 is formed on the rear surface. As the insulation resin, for example, a polyimide resin may be used, and the film can be formed by the spin-coat method or printing method. Furthermore, the forming of film may be carried out by the roll-coat method or the curtain coat method. By applying a liquid insulation resin, the forming of the insulation resin film 12 can be at low cost. In addition, the sticking of a dry film thereon may be applied.

Next, as shown in FIG. 2F, after a glass supporting body 14 is bonded on the rear surface of the semiconductor substrate 1 through an adhesive (for example, ultraviolet cured type adhesive) 13, a resin through hole 15 having a small diameter is concentrically formed by irradiating a laser on the insulation resin 11 filled into the through hole 4. As the laser used for making the resin through hole 15, both CO₂ gas laser and YAG laser can be used.

Further, when a photosensitive insulation resin is used as the insulation resin 11 filled into the through hole 4, the resin through hole 15 can be also formed by exposure and development. At any cases, compared with the CVD method, it is possible to easily form the insulation resin layer having a sufficient thickness within the through hole 4. In addition, an insulation resin which exists on the Al electrode 3 of the front surface of the semiconductor substrate 1 is removed when forming the resin through hole 15 or at the other process when necessary.

Next, as shown in FIG. 2G, at the front surface of the semiconductor substrate 1 and at the inside wall surface and the bottom of the resin through hole 15, a layer 16 of conductive metal such as Ti, Ni, Cu, V, Cr, Pt, Pd, Au, and Sn (seeding layer metal is formed by the electroless plating method. Instead of the electroless plating method, vapor deposition method or the sputtering method may be used. By the vapor deposition method or the sputtering method, better conductor metal layer 16 can be formed.

Then, as shown in FIG. 2H, after a resist layer is formed, on the conductor metal layer 16 formed on the front surface of the semiconductor substrate 1, a resist pattern 17 is formed by exposure and development. As the resist, both liquid type and film type are allowed. And, by using the conductor metal layer 16 formed at the former process as an electrode, an electroplating layer 18 such as Ni/Cu, Cu, Cu/Ni/Au is formed. Subsequently, as shown in FIG. 2I, after removing the resist pattern 17, the conductor metal layer 16 used as the electrode is removed by etching. Thus, on a predetermined region of the semiconductor substrate 1 and on the inside wall surface and the bottom of the resin through hole 15, a conductor layer 19 of which the conductor metal layer 16 and the electroplating 18 are laminated is formed.

After then, as shown in FIG. 2J, when necessary, a protective film (wiring protect resin film) 20 is formed by coating or sticking on the front surface, and by the exposure and development an opening portion is formed. For forming of the protective film 20, both coating of a liquid resin and sticking of a resin film are allowable. If a flatness is necessary at the time of forming the protective film 20, the resin through hole 15 may be filled with a resin for forming the protective layer 20. Furthermore, it is allowed that prior to the forming of the protective film 20 the resin through hole 15 is filled with other resin.

And, when the conductor metal layer 16 is a Ni/Cu layer, or a Cu layer, at an open portion of the protective film 20, a conductor layer 21 such as Au or Ni/Au, is formed by the electroless plating. This conductor layer 21 can be used as a connecting electrode when a chip is mounted. Hence the conductor layer 21 can be formed on the through hole 4, but may be formed at the other place. As a connecting system, when a solder is used, the protective film 20 functions as a solder resist. Instead of the protective film 20, after coating or sticking a resist and exposing and developing to form a pattern, it is possible to form a conductor layer 21 such as a Au or a Ni/Au layer by the electroless plating method and to remove the resist, when the conductor metal layer 16 is a Ni/Cu layer or a Cu layer. In this case, a solder resist is unnecessary.

Next, as shown in FIG. 2K, the glass supporting body 14 is stuck on the front surface of the semiconductor substrate 1 in place of the rear surface, and bonded through an adhesive 13. Subsequently, when the conductor metal layer 16 is a Ni/Cu layer or a Cu layer, an electroless plating layer 22 of Au or Ni/Au is formed to form a rear surface electrode.

Thereafter, the glass supporting body 14 is removed, as shown in FIG. 2L, when necessary, after a dicing tape 23 is stuck, a treatment such as the dicing is carried out. Thus, a rewiring layer is formed only on the front surface of the semiconductor substrate 1, thereby a semiconductor device having a connecting electrode formed on the through hole 4 and connectable with the other chip being obtained.

According to the second embodiment as mentioned above, a semiconductor device suitable for a structure of stacking a plurality of semiconductor chips, and having a high reliability can be manufactured. And the manufacturing method is not necessary to use an expensive apparatus such as the RIE. In addition, since the method does not have much processes of mask exposure processes and developing processes, it is possible to obtain the semiconductor device with low cost.

Further, the forming of the through hole 4 to the semiconductor substrate 1 is carried out by the laser irradiating, and the inside wall of the through hole 4 is formed of silicon having an amorphous structure. Then the insulation resin 11 filled into the through hole 4 is strongly adhered with the inside wall of the through hole 4. In addition, the inside wall surface of the through hole 4 is completely covered with the insulation resin 11 which extends to the rear surface of the semiconductor substrate 1. Accordingly, the insulation between silicon constituted of the inside wall of the through hole 4 and the inner conductor metal layer 16 is secured with the insulation resin 11, thereby the through via (conductive portion) having a high reliability being formed.

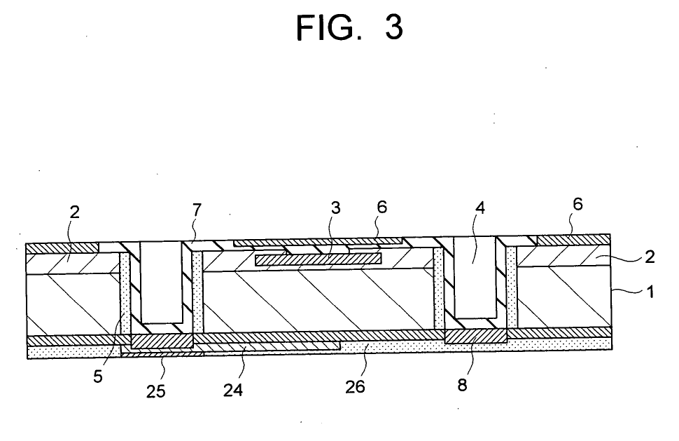

Next, we will describe other embodiments according to the present invention. FIG. 3 is a cross-sectional drawing showing a semiconductor device according to a third embodiment. In FIG. 3, reference number 24 shows a wiring layer at the rear surface side of the semiconductor substrate 1. This wiring layer 24 has a structure in which an electrolysis plating layers such as a Ni/Cu, Cu, and Cu/Ni/Au layer are laminated and formed on a conductor metal layer (seeding layer metal). And reference number 25 indicates an electroless plating layer such as a Au and Ni/Au layer, and number 26 indicates a protective film (wiring protective resin film). In FIG. 5, at the same portions with portions in FIG. 1, the same reference numbers. as those of the first embodiment shown in FIG. 1 is labeled. Therefore, the explanation thereof is omitted.

In the semiconductor device according to the third embodiment, as shown in FIG. 3, in addition to the front surface of the semiconductor substrate 1, a wiring layer 24 is also formed on the rear surface thereof. In the rear surface of the semiconductor substrate 1, on the wiring layer 24 drawn out from the through via, a connecting electrode with other semiconductor device is formed.

For manufacturing the semiconductor device according to the third embodiment, similarly with the second embodiment, processes shown in FIG. 2A to FIG. 2J are carried out in turn, and then the glass supporting body 1 being on the rear surface is changed to stick on the front surface of the semiconductor substrate 1. And, on whole rear surface including the through hole 4 of the semiconductor substrate 1, a conductor metal layer (seeding layer metal) is formed by an electroless plating method, evaporation depositing method, or sputtering method.

Subsequently, a resist is formed on the conductor metal layer, and after exposing and developing, an electrolysis plating layer such as Ni/Cu, Cu, or Cu/Ni/Au is formed by using the conductor metal layer as an electrode. After removing the resist, the conductor metal layer used as an electrode is removed by etching. Thereafter, a protective film is formed on the rear surface, and after forming an opening portion by exposing and developing, a layer such as an Au or Ni/Au layer is formed in the opening portion by electroless plating. This electroless plating layer is used as a connecting electrode at the time of element mounting, thus the layer can be formed on the through hole, but also may be formed on the other place except the through hole.

Thereafter, the removing of the glass supporting body and dicing treatment are carried out. Thus, re-wiring is formed not only on the front surface but also on the rear surface of silicon wafer, and a semiconductor device in which a connecting electrode with the other electrode is formed on a wiring drawn from the through via can be obtained.

In the manufacturing processes of the second and third embodiments, an example of forming a wiring on the front surface and the rear surface of the semiconductor substrate by the semi-additive method is described. Instead of the semi-additive method, a full-additive method or a subtract method can be used to form a wiring. Also, in the manufacturing method of the third embodiment, a glass supporting body is stuck on one surface (front surface) of the semiconductor substrate 1, and a conductor metal layer (seeding layer metal) is formed, and further in similar processes with the processes shown in FIG. 2H and FIG. 2I, a resist is formed and a wiring pattern is formed. Subsequently, the glass supporting body being on the front surface is changed to stick on another surface (rear surface), a wiring pattern is similarly formed. However, it is possible to form without using the glass supporting body. In this case, after forming a through hole, it is possible to form a conductor metal layer on the both surfaces of the semiconductor substrate and on an inside wall of the through hole by plating, in turn or simultaneously. Further, the forming of a resist is carried out on both surfaces in turn or simultaneously. And the forming of wiring layer on both surfaces of the semiconductor can be carried out simultaneously. At this time, it is possible to form a conductor metal layer on the inside wall surface of the through hole by plating simultaneously. According to this method, there is an advantage that the forming of the conductor layer of through via and the wiring are carried out simultaneously with lesser processes (plating process).

Next, other embodiments of the present invention will be described.

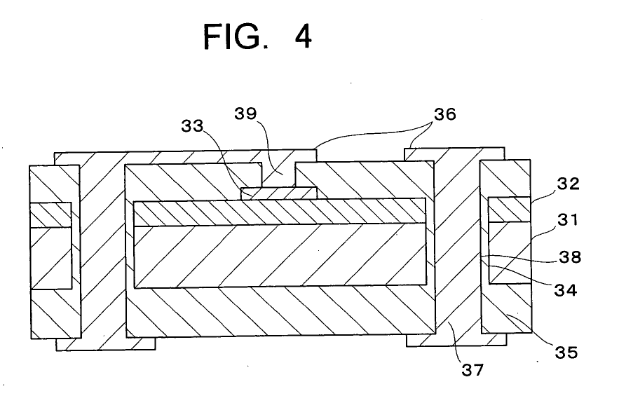

FIG. 4 is a cross sectional view showing a semiconductor device according to the fourth embodiment of the present invention. In FIG. 4, reference number 31 indicates a semiconductor substrate such as a silicon wafer. The front surface side thereof is an element region, and an integrated element portion and a multi-wiring portion 32 connecting between respective elements are formed.

Further, on the front surface of the semiconductor substrate 31, an electrode pad 33 connected with the multi-wiring portion and to use for signal transmission with the outside is formed. The semiconductor substrate 31 has a through hole 34 passing through the front surface and rear side thereof. On the front and rear surfaces of the semiconductor substrate 31 having the through hole 34, resin sheets each having a copper foil on one side surface are laminated to contact with the resin surface thereof, and on an inner surface (inside wall surface) of the through hole 34 and on the front and rear surfaces of the semiconductor substrate 31, an insulation resin layer 35 formed by the laminated resin sheets each having a copper foil on one side is covered.

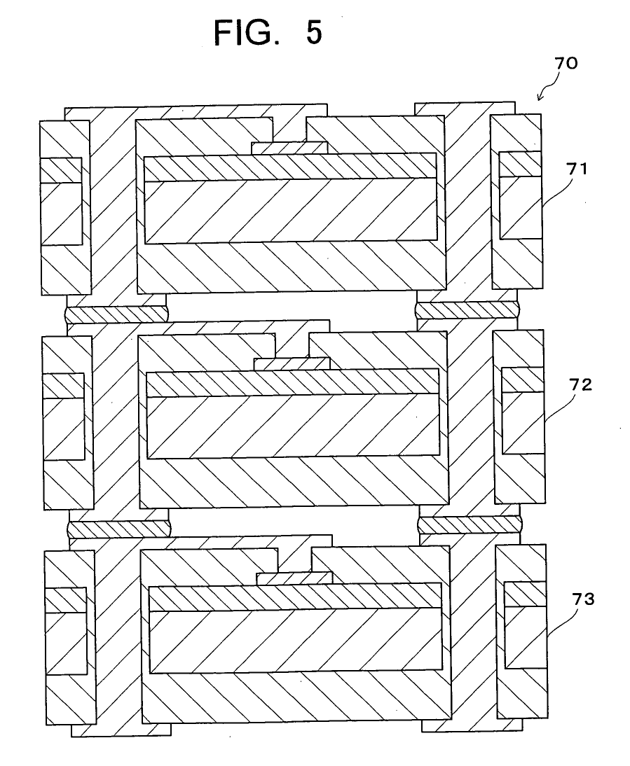

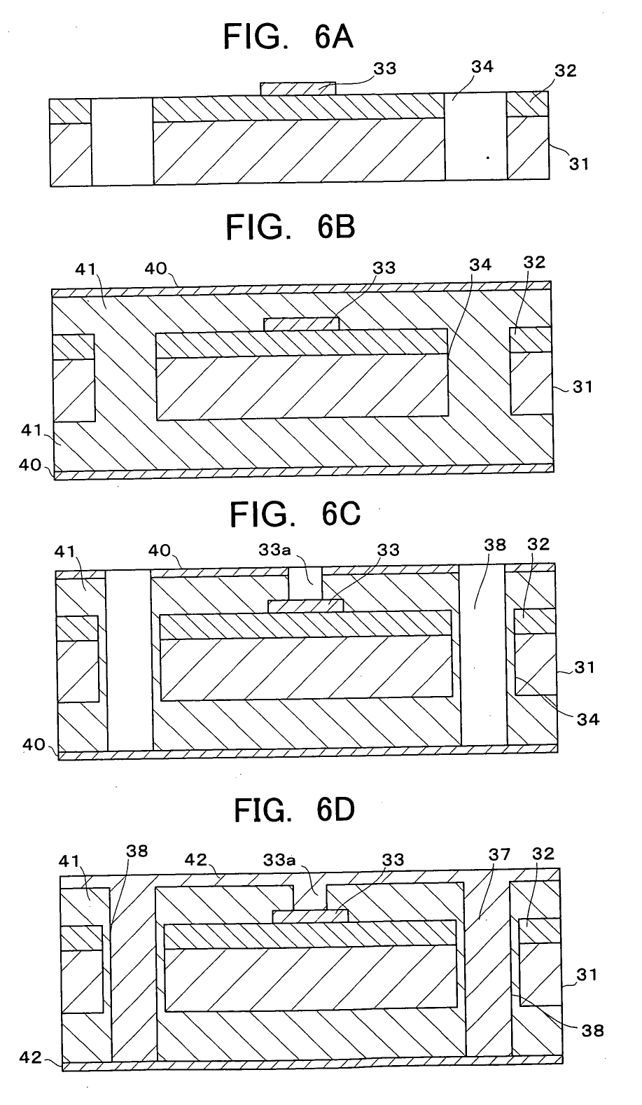

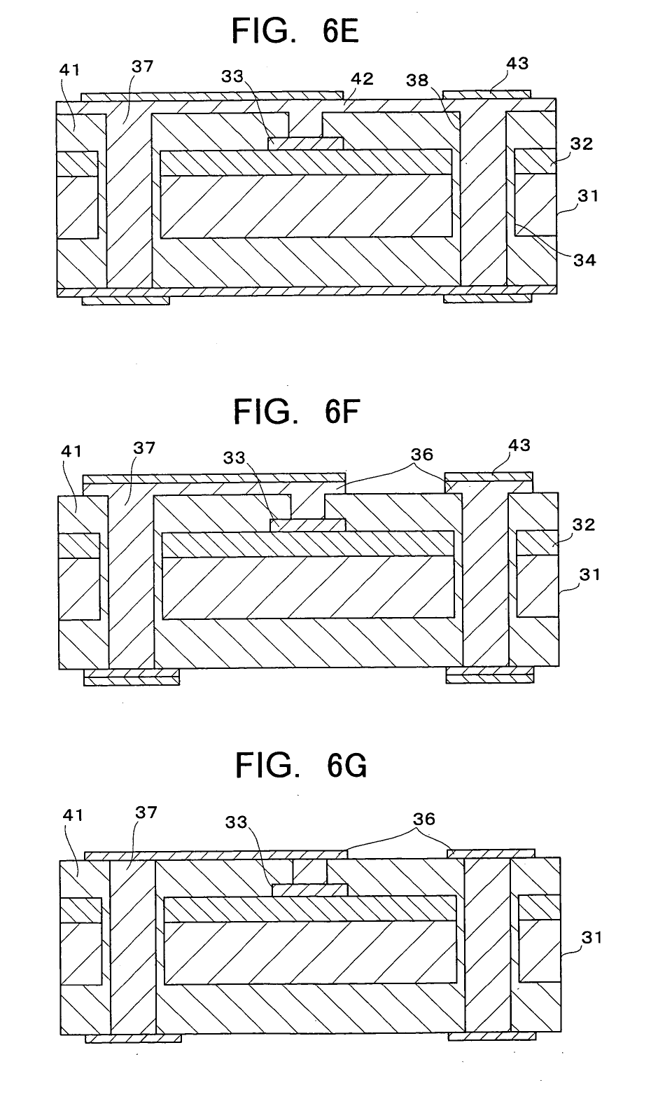

In addition, in the outside of the insulation resin layer 35 formed on front and rear surfaces of the semiconductor substrate 31, a wiring layer 36 is formed. The wiring layer 36 has a two layered structure composed of a copper foil pattern layer which is formed by patterning the copper foil of the resin sheet with a copper foil on one side and a copper plating layer formed thereon. A plating layer of Ni/Au and the like can be formed on the copper plating layer. And on the insulation resin layer 35 within the through hole 34, a post 37 formed of a conductor such as Cu is formed. Reference number 38 in FIG. 6 indicates a resin hole which is formed in the insulation resin layer 35 disposed in the inside of the through hole 34 and having a diameter smaller than that of the through hole 34. Further, reference number 39 is a conductor (copper) formed in an opening of the insulation resin layer 35 at the electrode pad 33 portion.

In the semiconductor device of the fourth embodiment as mentioned above, since the insulation resin layer 35 and the wiring layer 36 are formed by using an insulation resin sheet with one side copper foil, the semiconductor device is composed of relatively cheap member for a print circuit board. Further, since the wiring layer 36 has a two layered structure composed of a copper foil pattern layer formed by patterning the copper foil of the insulation resin sheet with a copper foil at one side surface thereof and a copper plating layer formed thereon, the adhesive strength with the insulation resin layer 35 which is a base layer is strong and the resistance to the impact is excellent. That is, a copper foil pattern layer formed by laminating the resin sheet with a copper foil at one side has many fine unevenness at the interface with the insulation resin layer 34. Accordingly, the copper foil pattern has an excellent adhesive strength compared with a copper plating layer which is directly formed on the insulation resin layer 35. Concretely, the measured value of peeling test at 90° C. of the copper plating layer is in the range 0.6 to 0.8 Kgf/cm. In contrast, the measured value of the copper foil layer formed by laminating is 1.5 Kgf/cm which is increased to a large extent.

Further, in the semiconductor device of this embodiment, as shown in FIG. 5, it is possible to simply realize a semiconductor stacked package (stack type multi-chip package) 70 having a small occupied space and structured by laminating plural semiconductor devices (semiconductor chip) 71, 72, and 73 in a longitudinal direction. As such semiconductor stacked package 70, for example, a stacked package of plural memory chips, a memory and logic stacked package, a stacked package in a module using a sensor chip, and the like are exemplified.

Next, we will describe the fifth embodiment which is a manufacturing method of the semiconductor device according to the fourth embodiment mentioned above, with reference to FIGS. 6A, 6B, 6C, 6D, 6E, 6F and 6G. In the embodiment, as shown in FIG. 6A, on a semiconductor substrate 31 which has an element portion and a multi-wiring portion (silicon wiring layer) 32 and an electrode pad 33 formed on the front surface thereof, for example, a laser is irradiated to form a through hole 34. The through hole 34 is allowed to be in any position on the semiconductor substrate 31 (semiconductor chip), and can be formed in the position suitable for connecting to other package or parts. Also, the hole diameter of the through hole 34 is varied depending on a thickness of the semiconductor substrate 31, but is about 0.02 to 0.1 mm.

Next, as shown in FIG. 6B, a sheet of an insulation resin 41 having one surface on which a copper foil 40 is stuck (resin sheet with a copper foil at one surface) is laminated on both surfaces of the semiconductor substrate 31 such that the surface of resin contacts to the semiconductor substrate 31. Thus, while the both surfaces of the semiconductor substrates 31 are covered with the insulation resin 41, the insulation resin 41 is filled into the through hole 34. The laminating process is carried out with a vacuum hot pressing similar to the manufacturing process of a printing wiring substrate. In the fourth embodiment, for example, an insulation sheet with a copper foil at one surface having a resin thickness of about 30 μm and a copper foil thickness of 12 μm is used.

Subsequently, as shown in FIG. 6C, a resin hole 38 having a diameter smaller than that of the through hole 34 is formed in the insulation resin 41 filled within the through hole 34, and an opening 33a is formed in the insulation resin 41 being at the upper portion of the electrode pad 33 on the front surface of the semiconductor substrate 31. This opening treatment of the insulation resin 41, that is, the forming of the resin hole 38 and the opening 33a can be implemented by using a laser processing machine. A diameter of the resin hole 38 is, for example, about 70 μm. And in the embodiment, although the resin hole 38 is a non-through hole whose one side only is opened, but it is allowed that the resin hole is a through hole in which the copper foils 40 at the both sides of the semiconductor substrate 31 are opened.

Next, a metal plating such as a copper plating is carried within the resin hole 38 and the opening 33a on the electrode pad 33 and on the copper foil 40. By this plating treatment, as shown in FIG. 6D, a conductor post 37 is formed within the resin hole 38. Further, on the front and rear surfaces of the semiconductor substrate 31, a conductor layer 42 for forming wiring with the copper foil 40 and a copper plating layer formed on the copper foil 40 is formed. In this embodiment, the insides of the resin hole 38 and the opening 38a are plated to completely fill, but only an inside wall surface and a bottom portion of the resin hole 38 may be plated to form a conductor plating layer.

Next, as shown in FIG. 6E, on a predetermined place of the conductor layer 42 for forming a wiring which is formed on both front and rear surfaces of the semiconductor substrate 31, an etching resist 43 is formed. Thereafter, as shown in FIG. 6F, an etching treatment of the conductor layer 42 for forming a wiring is carried out by using this etching resist 43 as a mask to form a wiring layer 36 having a predetermined pattern. Then, as shown in FIG. 6G, by removing the etching resist 43, a finished state is obtained. The actual manufacturing processes are performed in a state of a semiconductor wafer. After obtaining the finished state, a dicing process is carried out to be a finished product of each chip.

As described above, in the fourth and fifth embodiments, processes other than the process of forming a through hole 34 of the semiconductor substrate 31 can be performed with the same method as the manufacturing method of a print wiring board, consequently, it is possible to manufacture the semiconductor device with a low cost and simply compared with the conventional method.

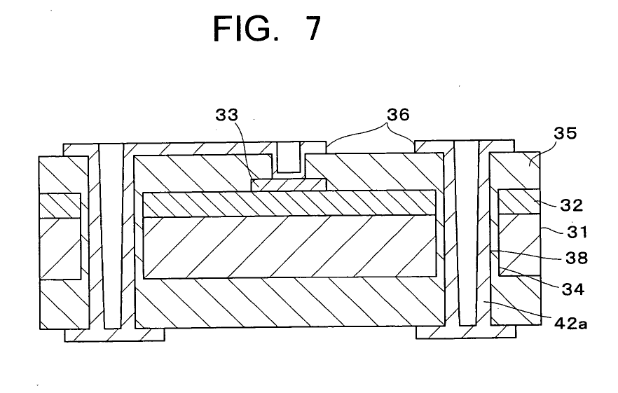

FIG. 7 is a cross sectional view showing a structure of a semiconductor device according to a sixth embodiment. In FIG. 7, the same portions as those of the semiconductor device shown in FIG. 4 have the same reference number, hence the explanation thereof is omitted. The semiconductor device of the sixth embodiment has a structure of which insides of the resin hole 38 and opening 38a mentioned above are not fully filled with a conductor plating layer. That is, a conductor plating layer is only at the inside wall and the bottom in the resin hole 38 and in the opening 33a, electrodes at the both surfaces is electrically connected by a tube shaped conductor 42a formed in the resin hole 38.

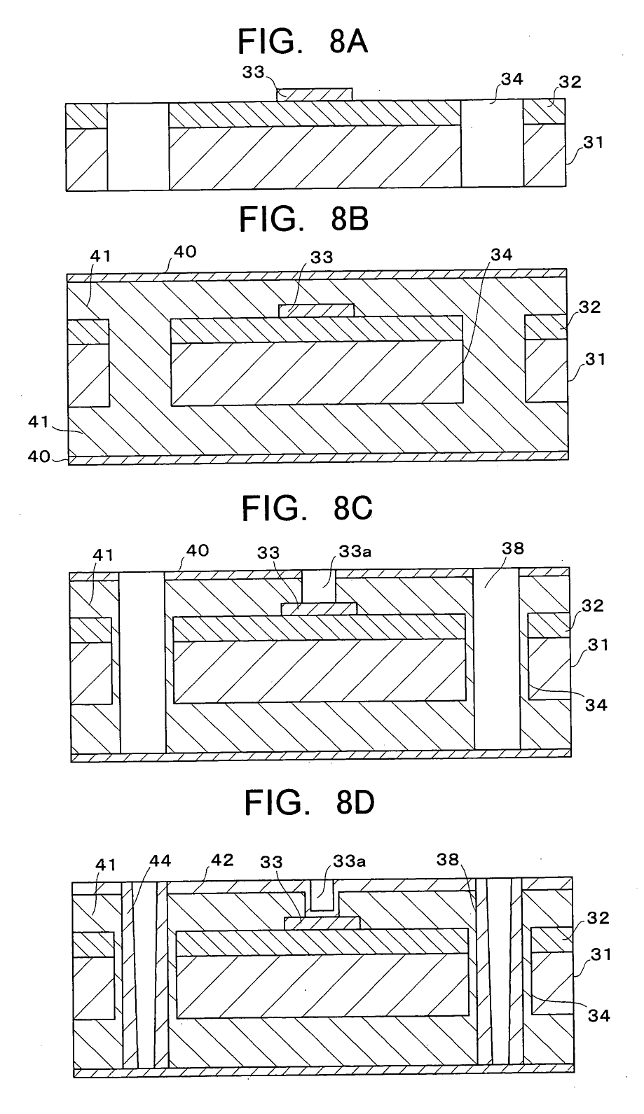

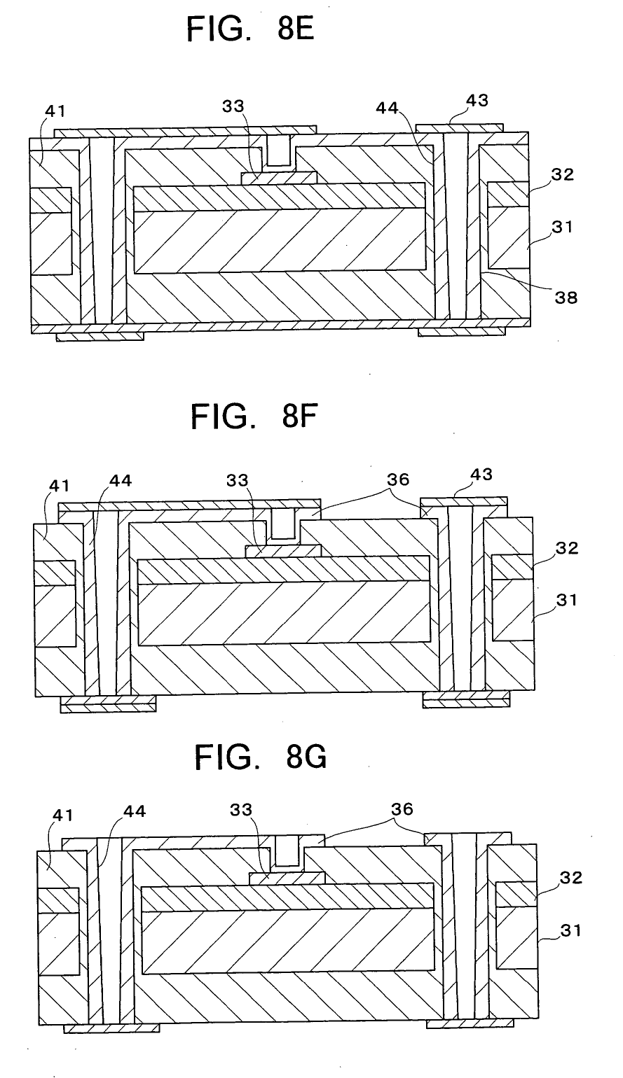

The semiconductor substrate 31 of the sixth embodiment is manufactured according to the respective steps shown in FIG. 8A to FIG. 8G. FIG. 8A to FIG. 8G are cross sectional views showing the manufacturing process of a semiconductor device according to the seventh embodiment. In FIG. 8A to FIG. 8G, the same reference number is marked to portions corresponding to the manufacturing steps shown in FIG. 6A to FIG. 6G. Thus, the explanation thereof is omitted. In the manufacturing process of the semiconductor device, a plating treatment step shown in FIG. 8D is only different from that of the fifth embodiment shown in FIGS. 6A to 6G. That is, by controlling the condition of plating, the conductor plating layer 44 is formed at the inside wall and the bottom in the resin hole 38 and in the opening 33a. In this manufacturing method of the semiconductor device, it is also possible to manufacture the semiconductor device with low cost and simply.

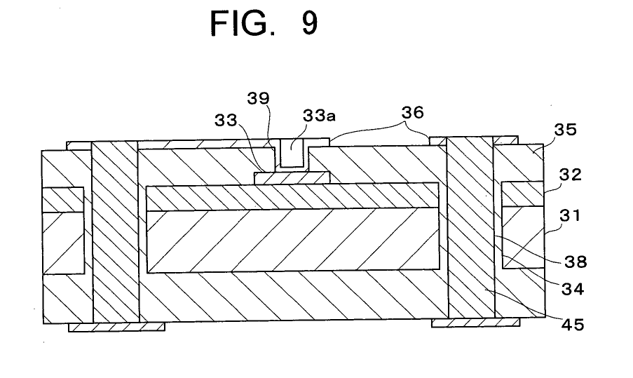

FIG. 9 is a cross sectional view showing a structure of a semiconductor device according to a eighth embodiment. In FIG. 9, the same reference number is marked to the same portion as that of the semiconductor device shown in FIG. 4. Thus, the explanation thereof is omitted. In the semiconductor device of the eighth embodiment, a conductor portion in the resin hole 38 is not formed by plating treatment. The conductor portion has a structure of which a conductive resin 45 is filled into the resin hole 38. And, due to the filling layer of this conductive resin 45, electrodes at both surfaces of the semiconductor substrate 31 are electrically connected.

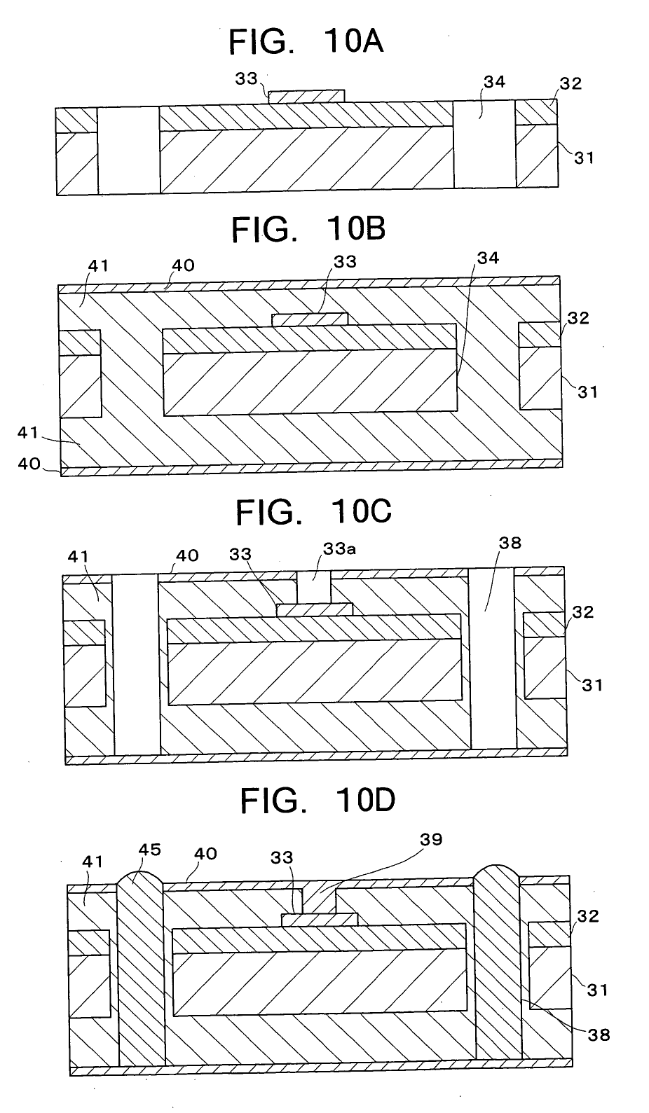

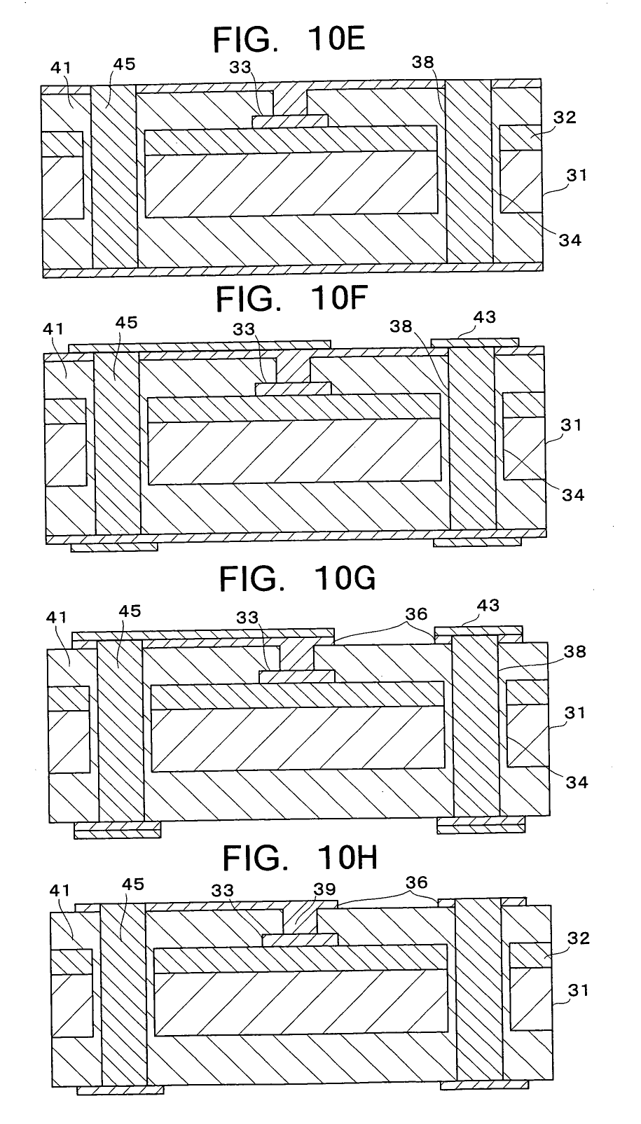

The semiconductor device according to the eighth embodiment is manufactured according to the steps shown in FIG. 10A to FIG. 10H. FIG. 10A to FIG. 10H are cross sectional views showing the manufacturing steps of the semiconductor device according to the ninth embodiment. In this embodiment, instead of plating treatment process shown in FIG. 6D, a filling process of a conductive resin 45 into a resin hole 38 as shown in FIG. 10D and a polishing process of the conductive resin 45 at the front side as shown in FIG. 10E are performed. With regard to the other respective processes, the processes of the embodiment are the same as those of the fifth embodiment shown in FIGS. 6A to 6G. According to the manufacturing method of the semiconductor substrate mentioned above, it is possible to manufacture the semiconductor device with the lower cost an simply.

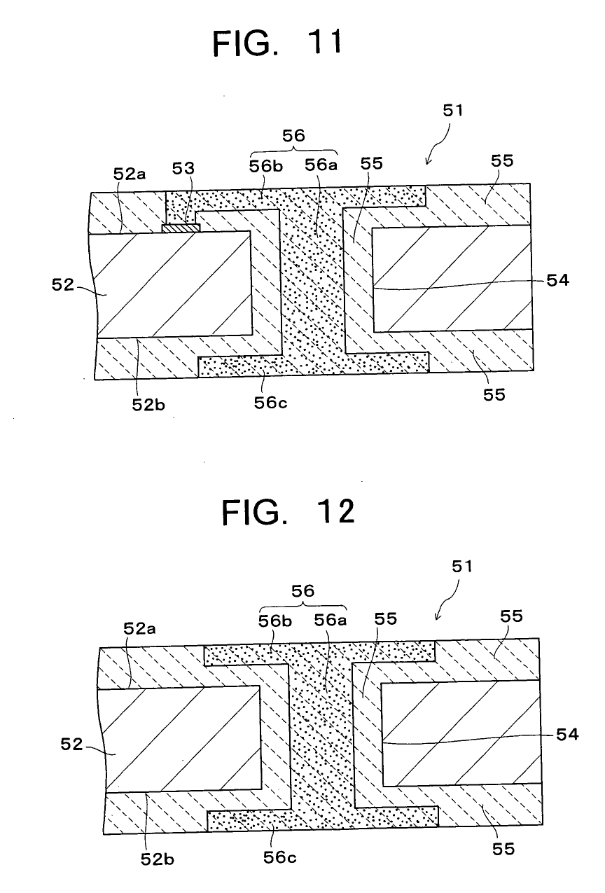

FIG. 11 is a cross sectional view of a structure of the semiconductor device according to a tenth embodiment of the present invention. The semiconductor device 51 shown in this FIG. 11 has a semiconductor substrate (such as a silicon substrate) 52, in which an arithmetic element portion, a memory element portion, a function element such as a sensor element portion and the like are formed by using a usual semiconductor process. That is, the front surface 52a side of the semiconductor substrate 52 is an element region, and an integrated element portion and a multi-layer wiring portion connecting between respective elements are formed (illustrations thereof are omitted). On the front surface 52a of the semiconductor substrate 52, an electrode 53 which is connected to an inside of the multi-layer wiring portion is formed.

At a peripheral portion of the semiconductor substrate 52, a through hole 54 having a diameter of about 20 to 100 μm is formed. That is, the semiconductor substrate 52 has the through hole 54 connecting between the front surface 52a and the rear surface 52b. In the through hole 54, a porous insulation resin layer 55 is filled, and further, the porous insulation resin layer 55 is formed to cover both the front and rear surfaces 52a, 52b of the semiconductor substrate 52, while continuing from an inside of the through hole 54.

This porous insulation resin layer 55 is formed, for example, by a method of dispersing liquid having low boiling point, nitrogen or carbon dioxide charged in high pressure in the resin and heating them to form bubble, a method of heating and decomposing foaming agent dispersed in a resin to generate a gas and form bubble, or a method of dispersing an organic compound with non-compatibility in the polymeric type monomer, curing the polymeric type monomer and removing the non-compatible organic compound to form fine holes, and other known porous resin manufacturing methods can be applied.

Here, forming material of the porous insulation resin layer 55 is not particularly limited. Corresponding to the manufacturing method of porous resin, various insulation resins (organic insulation) can be used. As an example, a porous insulation resin layer 55 formed of a polyimide resin is exemplified.

Further, the porous insulation resin layer 55 has an inner structure in which fine empty holes are continued in a three-dimensional structure such that a conductor layer mentioned below can be formed in an empty through surface at the inside thereof. In order to obtain such inner structure, the empty hole degree of the porous insulation resin layer 55 (volume percentage of empty hole to an apparent volume of the insulation resin layer) is desirable in a range of 40 to 90%. When the empty hole degree of the porous insulation resin layer 55 is less than 40%, a communication state of empty holes is decreased, there is the possibility that the conductor layer becomes in a non-continuous state. In contrast, when the empty hole degree exceeds 90%, since the strength of the porous insulation resin layer 55 itself is damaged, there is the possibility that a layer state and a filling state can not be maintained.

In the porous insulation resin layer 55 mentioned above, a conductor layer 56 is selectively formed. Namely, at an inside surface of an empty hole in the porous insulation layer 55 (surface of resin forming an empty hole), a conductive metal such as copper or aluminum is precipitated thereon by the electroless plating and the like, thereby a continuous conductor layer 56 being selectively formed.

Such a conductor layer 56 has a conductor post portion 56a which is continuously formed in the inside of the porous insulation resin layer 5 within the through hole 54 so as to connect between the front and rear surfaces 52a, 52b of the semiconductor substrate 52. The conductor post portion 56a being in the through hole 54 functions as a connecting plug connecting between the front surface 52a and the rear surface 52b of the semiconductor device 51.

Here, the conductor post portion 56a is necessary to be insulated from an inner surface (side wall surface) of the through hole 54 formed of silicon and the like which is a structural material of the semiconductor substrate 52. Therefore, it is desirable that the conductor post portion 56a is selectively formed at a position separated with a distance of μm or more from the inner surface of the through hole 54. That is, between the conductor post portion 56a and the inner surface of the through hole 54, there is the porous insulation resin layer 55 in which a conductor is not filled, and this unfilled porous insulation resin layer functions as an insulation layer.

The conductor post portion 56a can be formed in the porous insulation resin layer at an arbitrary position and with an arbitrary depth. Therefore, it is possible to provide a porous insulation resin layer 55 which functions as an insulation layer between the conductor post portion 56a and the inner surface of the through hole 54, with an arbitrary thickness (for example 1 μm or more) and with reproducibility. Thus, the insulation reliability of the conductor post portion 56a can be improved.

Further, the conductor layer 56 has a part 56b which is continuously formed from the conductor post portion 56a being in the through hole 54, and is formed in the inside of the porous insulation resin layer 55 covering the front surface 52a of the semiconductor substrate 52. The conductor layer 56b at the front surface side is a part electrically connecting between the conductor post portion 56a in the through hole 54 and the electrode 53, and is formed in response to the desired wiring pattern.

It is also desirable like with the inside the through hole 54 that the conductor layer 56b at the front surface side is provided at a position separated from the front surface 52a of the semiconductor substrate 52, for example, with a distance of 1 μm or more. As described above, since the conductor layer 56 can be formed at an arbitrary depth region of the porous insulation resin layer 55, the porous insulation resin layer 55 functioning as an insulation layer can be provided with reproducibility between the conductor layer 56b at the front surface side and the front surface 52a of the semiconductor substrate 52. Therefore, with regard to the front surface side conductor layer 56b, it is also to improve the insulation reliability to the front surface 52a of the semiconductor substrate 52.

With respect to a connecting portion between the front surface side conductor layer 56b and the electrode 53, the forming region of the conductor layer 56b to the porous insulation resin layer 55 is deepened only at the connection portion, thereby a good electrical connecting being obtained easily and securely without any complex process. Also, at the rear surface 52b side of the semiconductor substrate 52, a conductor layer 56c having a land-shape which is a connecting portion with other semiconductor device and/or wiring substrate. It is also desirable to form this rear surface side conductor layer 56c at a position separated from the rear surface 52b of the semiconductor substrate 52, for example, with a distance of 1 μm or more. In addition, at the rear surface 52b side of the semiconductor substrate 52, the conductor post portion 56a in the through hole 54 can be allowed to leave in the position.

The porous insulation resin layer 55 in which a conductor layer 56 is formed is allowed to a practical use for the semiconductor device 51, but it is desirable to fill a second insulation resin into the whole empty hole of the porous insulation resin layer 55 and cure them, because portion in which conductor layer 56 is not filled has a poor mechanical strength. As the second insulation resin for filling the empty hole of the porous insulation layer 55, for example, a thermosetting resin compound in a varnish state is filled by applying the press fit, the vacuum impregnation or the like and is cured by using a thermal treatment and the like. As mentioned above, by filling the remaining empty hole in the porous insulation resin layer 55, the strength of the semiconductor device 51 can be maintained.

As described above, in the porous insulation resin layer 55, the conductor layer 56(56a, 56b and 56c), which extends from the electrode 53 on the front surface side 52a of the semiconductor substrate 52 to the rear side 52b through the inside of the through hole 54, is selectively formed. The conductor layer 56 functions as a wiring layer which draws a wiring of electrode 53 at the front surface 52a side to the rear surface 52b side. And the insulation to the front and rear surfaces 52a, 52b of the semiconductor substrate 52 and an inner surface (sidewall surface) of the through hole 54 is maintained by the porous insulation resin layer 55. Therefore, the conductor layer 56 is excellent as a wiring layer in the semiconductor device 51 in the reliability. Also, the decline of yield and the deterioration of action property due to bad quality of insulation can be effectively suppressed. The forming steps thereof can be extremely simplified and the cost thereof can be largely reduced compared with the conventional semiconductor process.

The conductor layer 56 connecting between the front surface 52a and the rear surface 52b functions, for example, as a connecting plug which connects between semiconductor devices and/or which connects between a semiconductor device and a wiring substrate, when composes a stack type multi-chip package of which a plurality of semiconductor devices 51 are stacked and sealed. As the stack type multi-chip package, a multi-chip module of which a plurality of memory elements are mounted, or a system LSI module of which a logic element and a memory element are stacked, is examplified.

Further, in case of s semiconductor device having a sensor function such as a photo-image sensor element, in a state of arranging a sensor portion on the front surface side, the semiconductor device can be connected and mounted on the mounted substrate and the like, with a wiring layer (conductor layer 56) drawn at a rear surface side.

The tenth embodiment shown in FIG. 11 shows an example of which a conductor layer 56 is applied to a wiring layer of electrode 53, but as shown in FIG. 12, it is possible to apply the conductor layer 56 to a through plug only connecting between the front and rear surfaces 52a, 52b of the semiconductor substrate 52. That is, the semiconductor device shown in FIG. 12 has a conductor post portion 56a which is selectively and continuously formed inside of the porous insulation resin layer 55 being in the through hole 54. And, at each of the front surface 52a side and the rear surface 52b side of the semiconductor substrate 52, a land shaped conductor layer 56d which is a connecting portion with other semiconductor device or a wiring substrate is formed. The conductor layer 56 (56a, 56d) functions as a through plug which connects with the other semiconductor device or a wiring substrate disposed above and below the semiconductor device 51.

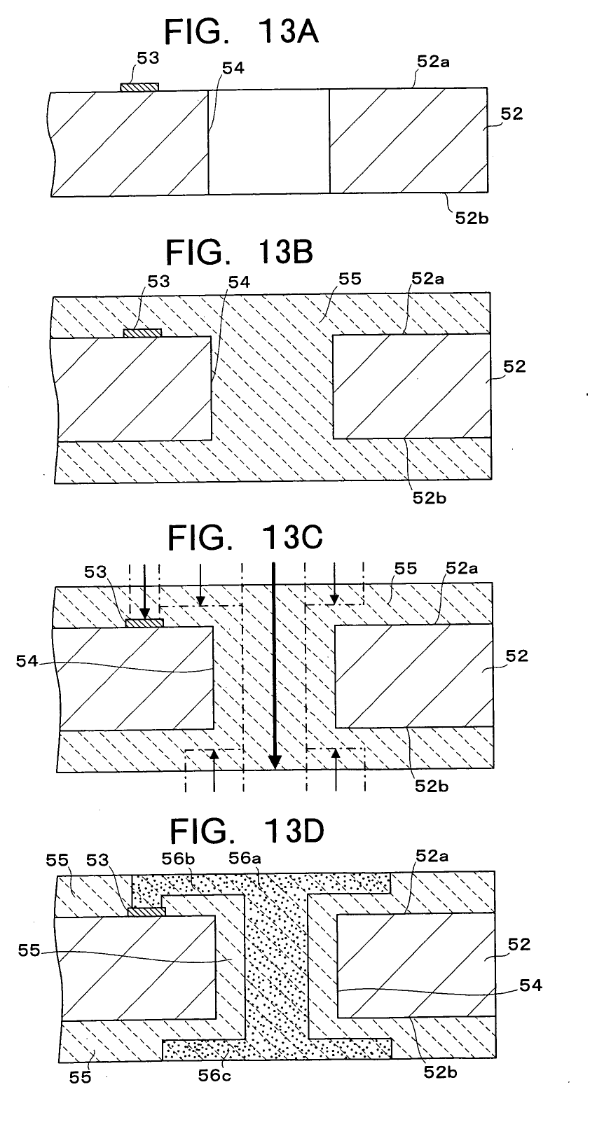

Next, we will describe an eleventh embodiment which is a manufacturing method of the semiconductor device according to the tenth embodiment, with reference to FIG. 13A, 13B, 13C and 13D. In the eleventh embodiment, first as shown in FIG. 13A, in a semiconductor substrate 52 having an integrated element portion, a multi-layer wiring portion (illustration thereof is omitted), and an electrode 53 on a front surface 52a side, a through hole 54 passing through between the front and rear surfaces is formed. The forming of the through hole 54 can be implemented, for example, by a laser irradiating or an etching processing and the like.

Subsequently, as shown in FIG. 13B, a porous insulation resin layer 55 is formed to cover both front and rear surfaces 52a, 52b of the semiconductor substrate 52 and to fill the inside of the through hole 54. The porous insulation resin layer 55, for example, is formed as the following.

First, a varnish like insulation resin compound for forming a porous layer is coated on the both front and rear surfaces 52a, 52b of the semiconductor substrate 52, and filled into the through hole 54. With respect to the coating and filling of the insulation resin compound, for example, by applying a process of removing a non-compatible organic compound which is dispersed in the insulation resin compound (process of making porous), the insulation resin compound can be cured and can be made to be porous. As the porous insulation resin layer 55 obtained by the above process, for example, a porous polyamideimide layer is exemplified. The degree of empty hole is desirable in a range of 40 to 90%, as previously described.

When forming the porous insulation resin layer 55, much varnish type insulation resin compound is necessary to fill in the through hole 54, and an amount of resin becomes insufficient compared with the plain portion of front and rear surfaces 52a, 52b of the semiconductor substrate 52. Therefore, there is a case that a lack of resin layer is formed in the filling portion and the flatness is injured. And, when the varnish type insulation resin layer is cured, the same phenomena is occurred with the shrinkage due to curing. Thus, if a dent is produced to injure its flatness in the portion corresponding to the through hole 54 of the porous insulation resin layer 55, there is the possibility that any trouble is produced at the time of connecting with other semiconductor device or wiring substrate.

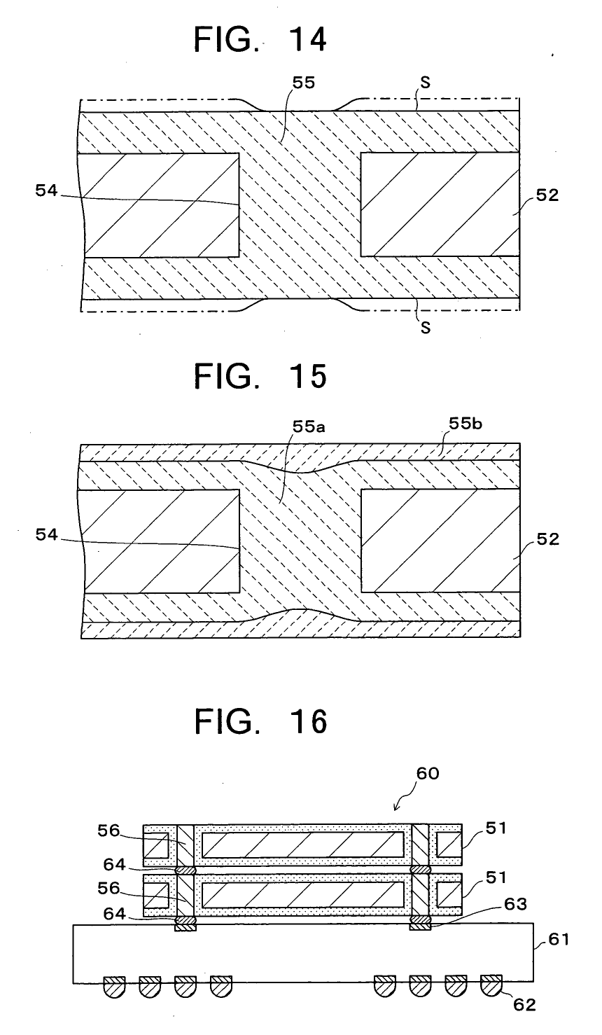

Then, as shown in FIG. 14, it is desirable to polish and flatten the surface of the porous insulation resin layer 55 of which the dent was produced in the portion corresponding the through hole 54. In FIG. 14, S shows a surface to be polished. As shown in FIG. 15, it is desirable to plural times repeat the coating and curing of the varnish type insulation resin compound so that the porous insulation resin layer 55 is to be flatten. In FIG. 15, reference number 55a indicates a porous insulation resin layer formed by the first treatment, and number 55b indicates a porous insulation resin layer formed by the second treatment. The flatness of the porous insulation resin layer 55 is desirable to set such that the depth of dent in the portion corresponding to the through hole 54 is to be 2 μm or less to the flat portion.

Subsequently, after treating the porous insulation resin layer 55 with a photosensitive agent, as shown in FIG. 13C, the porous insulation resin layer 55 is subjected to exposure in response to the state of the conductor layer 56 to be formed. Here, an arrow in the drawing shows a light for exposure. The treatment with the photosensitive agent, for example, is carried out by such that the semiconductor substrate 52 having the porous insulation resin layer 55 is immersed in the photosensitive agent solution and is dried. By such treatment, the photosensitive agent is coated on the whole including a surface of the empty hole being inside of the porous insulation resin layer 55. Still more, since the photosensitive agent is coated with extremely thin thickness on an inner surface of the empty hole, a porous state can be maintained.

The exposure treatment of the porous insulation resin layer 55 is implemented, for example, with respect to the part of the through hole 54, to pass through between the front and rear surfaces 52a, 52b over the whole thickness direction. At this time, the region to be exposed is controlled such that the exposure portion is to be separated from the inner surface (inside wall surface) of the through hole 54 with a predetermined distance (for example, 1 μm or more). Also, the exposure for the wiring pattern portion at the front surface 52a side and a land portion at the rear surface 52b side of the semiconductor substrate 52, is carried out to be exposed to a predetermined depth of the porous insulation resin layer 55. That is, the exposure is carried out to expose until a position separated from respective surface with predetermined distance (for example, 1 μm or more). A connection portion to the electrode 53 is similarly treated such that the exposure portion arrives to the electrode 53. The depth to be exposed can be controlled in response to the amount of exposure (the amount of irradiation of light).

Such exposure treatment, in response to respective regions (connecting plug portion, wiring pattern portion, connecting portion to an electrode, land portion and the like), can be together implemented to respective regions in the porous insulation resin layer 55 by using a mask which controls passing amount of light. For example, using a mask which passes through an entire light on a portion of the through hole 54 and a half of the light on the wiring pattern portions and land portions at both front and rear surfaces 52a, 52b, the porous insulation resin layer 55 is subjected to an exposure treatment. Next, an exposure portion of the porous insulation resin layer 55 is subjected to an activation-treatment to deposit a metal plate. The activation treatment is selectively carried out to the exposure portion.

Thereafter, the semiconductor substrate 52 having the porous insulation resin layer 54 on which the photosensitive treatment, the exposure treatment, the activation treatment were implemented in turn is immersed in an electroless copper plating liquid. In this plating treatment process, a plating metal such as copper is deposited only on a portion which was subjected to the exposure and activation. Therefore, as shown in FIG. 13D, in a portion of the through hole 54, a conductor layer such as a copper plating layer (conductor post portion 56a) is formed to connect between the both front and rear surfaces 52a, 52b. In response to respective wiring pattern and land shape, the conductor layers 56b, 56c are formed on the front surface 52a side and rear surface 52b side of the semiconductor substrate 52.

Thus, at the inner surface of the through hole 54 and between the front and rear surfaces 52a, 52b of the semiconductor substrate 52, the conductor layer 56 connecting between the front and rear surfaces 52a, 52b of the semiconductor substrate 52, with an insulation layer having a predetermined thickness (porous insulation resin layer 55 in which a conductor is not filled) is formed. After forming the conductor layer 56, if necessary, a process for filling a second insulation resin into a remaining empty hole of the porous insulation resin layer 55 and a process of curing them are implemented. The filling process of the second insulation resin can be carried out by applying the press injection method or vacuum impregnation method, as mentioned above.

According to the manufacturing method of the semiconductor device of the eleventh embodiment, since the conductor layer 56 is selectively formed in the porous insulation resin layer 55, in addition to that the insulation to the inner surface of the through hole 54 and the insulation to the both front and rear surfaces 52a, 52b of the semiconductor substrate 52 are maintained in the better state through the porous insulation resin layer 55, it is possible to form a conductor layer 56 including the inside of the through hole 54 to a desired pattern with accuracy. Further, since the forming process of the conductor layer 56 and the insulation layer (porous insulation resin layer 55 in which a conductor is not filled) can be carried out by a simple method such as the coating of an insulation resin and the plating, the conductor layer 56 and the insulation layer can be formed with low cost. These processes attribute to decrease the manufacturing cost and improve the reliability of the semiconductor device 51 having a conductor layer 56 connecting between the front and rear surfaces 52a, 52b of the semiconductor substrate 52.

Next, we will describe a stack type multi-chip package having the semiconductor device of the present invention with reference to FIG. 16. A semiconductor device (semiconductor package) 60 of this embodiment has a wiring substrate 61 as a mounting substrate. As the wiring substrate 61, various substrates such as a resin substrate or a ceramic substrate can be applied. As the resin substrate, ordinary multi-layered printing wiring board is used. At a lower surface side of the wiring substrate 61, an exterior connecting terminal such as a metal bump is formed. On the other hand, at an upper surface side, an electrode portion 63 which is connected with the exterior terminal 62 through an inner wiring (illustration thereof is omitted) is provided.

On an element mounting face (upper surface) of the wiring substrate 62, a plurality of semiconductor device 51 described in the eighth embodiment are stacked and mounted. Here, FIG. 18 shows a semiconductor package 60 in which two semiconductor devices 51 are mounted on the wiring substrate 61. But mounting numbers of the semiconductor device is not limited to two pieces, it is allowed to be three or more pieces.

The lower side semiconductor device 51 is connected and fixed to the electrode portion 63 of the wiring substrate 61 through a bump 64 formed at a portion of the conductor layer 56. Similarly, the upper side semiconductor device 51 is connected and fixed to the conductor layer 56 of the lower side semiconductor device 51 through a bump 64 formed at a portion of conductor layer 56. Thus stacked plural semiconductor devices 51 are sealed with a sealing resin and the like (not illustrated), and the semiconductor package having a stacked type multi-chip package structure is constituted.

According to the semiconductor package 60, since a flip-chip connection can be applied to connect between semiconductor devices 51 and between the semiconductor device 51 and the wiring substrate 61, it is possible to decrease the cost and man-power for connecting process, and similarly to shorten a signal wiring length or miniaturize a package size. These attribute to decrease the cost of the stack type multi-chip package and improve the reliability and running property thereof. As a concrete example of the semiconductor package 60, a multi-chip module in which a plurality of memory elements are stacked and a system LSI module in which a logic element and a memory element are stacked can be provided.

Still more, the present invention is not limited to the embodiments described above, and can be applied to various semiconductor device having a conductor layer which connects by passing through between the front and rear surfaces of a semiconductor substrate. The above semiconductor device is included within the scope of the invention. Further, the embodiments of the invention can be extended or changed within the scope of technical idea of the invention, and the extended or changed embodiments are included within the technical scope of the invention.

What is claimed is:

1. A semiconductor device, comprising:
a semiconductor substrate having a through hole passing through between a front surface and a rear surface;
a first insulation resin layer formed on an inner surface of the through hole;
a second insulation resin layer formed on at least one of the front and rear surfaces of the semiconductor substrate; and
a first conductor layer formed in the through hole to electrically connect between the front and rear surfaces of the semiconductor substrate,
wherein the first conductor layer is insulated from the inner surface of the through hole with the first insulation resin layer.

2. The semiconductor device according to claim 1, wherein the semiconductor device further comprises a second conductor layer formed on a predetermined region of the second insulation resin layer, the second conductor layer being electrically connected with the first conductor layer.

3. The semiconductor device according to claim 2, wherein the second conductor layer comprises a copper foil which is processed to form a wiring.

4. The semiconductor device according to claim 3, wherein the processed copper foil has a plating layer formed thereon.

5. The semiconductor device according to claim 3, wherein a copper plating layer is formed on the processed copper foil.

6. The semiconductor device according to claim 1 or claim 2, wherein the through hole of the semiconductor substrate has an inner surface where a base material region having an amorphous structure is formed, and further the first insulation resin layer is formed on the inner surface.

7. The semiconductor device according to claim 1, wherein the first insulation resin layer and the second insulation resin layer are a porous insulation resin layer, and the first conductor layer is continuously formed within the porous insulation resin layer.

8. The semiconductor device according to claim 7, wherein the semiconductor substrate has an electrode formed on a surface at an element region side of the semiconductor substrate and the electrode is connected with the first conductor layer.

9. The semiconductor device according to claim 7, wherein the porous insulation layer has empty holes and a third insulation resin is filled in the empty holes.

10. A method of manufacturing a semiconductor device, comprising:
forming a through hole by irradiating a laser on a semiconductor substrate having an integrated element formed at a front surface thereof;
filling an insulation resin into the through hole;
forming concentrically a resin hole having a diameter smaller than that of the through hole; and
forming a conductor layer on an inner surface of the resin hole and forming a through hole conductive portion to electrically connect between the front surface and the rear surface of the semiconductor substrate.

11. The method of manufacturing a semiconductor device according to claim 10, wherein the forming of the resin hole is carried out by irradiating a laser on the insulation resin.

12. The method of manufacturing a semiconductor device according to claim 10, wherein the conductor layer is formed by plating the inner surface of the resin hole.

13. The method of manufacturing a semiconductor device according to claim 10, further comprises forming a desired wiring on at least one surface of the front and rear surfaces of the semiconductor substrate.

14. A method of manufacturing a semiconductor device, comprising:
forming a through hole in a semiconductor substrate;
disposing each resin sheet, which has a copper foil at one side thereof, on the both surfaces of the semiconductor substrate to contact with a resin surface of the each resin sheet, and laminating the disposed each resin sheet and the semiconductor substrate;
forming a small hole having a diameter smaller than that of the through hole at a portion of the through hole;
forming a conductor layer inside of the small hole, and electrically connecting the conductor layer with the copper foil disposed on both surfaces of the semiconductor substrate; and
processing the copper foil to form a wiring.

15. The method of manufacturing a semiconductor device according to claim 14, wherein the small hole is a non-through hole.

16. The method of manufacturing a semiconductor device according to claim 14 or claim 15, wherein the small hole is filled with the conductor layer.

17. A method of manufacturing a semiconductor device, comprising:
forming a through hole in a semiconductor substrate;
forming a porous insulation resin layer to cover a front surface and a rear surface of the semiconductor substrate including an inside of the through hole; and
forming a conductor layer within the porous insulation resin layer to connect at least between the front surface and the rear surface of the semiconductor substrate, while maintaining an insulation state from the front and rear surfaces of the semiconductor substrate and from an inner surface of the through hole.

18. The method of manufacturing a semiconductor device according to claim 17, further comprising filling a second insulation resin into empty holes of the porous insulation resin layer and curing the filled second insulation resin.
